(19) United States
(12) Patent Application Publication
(10) Pub. No.: US 2025/0096153 A1
(43) Pub. Date: Mar. 20, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chih-Hsien CHIU, Taichung City (TW); Wen-Jung TSAI, Taichung City (TW); Chien-Cheng LIN, Taichung City (TW); Chun-Chong CHIEN, Taichung City (TW); Shih-Shiung KUO, Taichung City (TW)

(21) Appl. No.: 18/426,574

(22) Filed: Jan. 30, 2024

(30) Foreign Application Priority Data
Sep. 18, 2023 (TW) 112135544

(51) Int. Cl. H01L 23/00; H01L 21/56; H01L 23/31; H01L 23/552

(52) U.S. Cl. CPC H01L 23/562; H01L 21/561; H01L 23/3128; H01L 23/552; H01L 24/16; H01L 24/32; H01L 24/73; H01L 2224/16225; H01L 2224/32225; H01L 2224/73204

(57) ABSTRACT

An electronic package and a manufacturing method thereof are provided, in which an electronic component is disposed on a substrate and covered with an encapsulation layer, and a frame body is embedded in the encapsulation layer and protrudes from the substrate. Therefore, the frame body can disperse thermal stress, thereby preventing warping from occurring to the electronic package.

### BACKGROUND

### 1. Technical Field

The present disclosure relates to a semiconductor device, and more particularly, to an anti-warp electronic package and a manufacturing method thereof.

### 2. Description of Related Art

Flip-chip semiconductor package is a packaging structure conducting electrical connection in a flip-chip manner, where the active surface of a chip is electrically connected to a substrate via a plurality of solder bumps, and a plurality of solder balls that can be served as input/output (I/O) terminals are placed on the other surface of the substrate. This design can not only greatly reduce the volume of packages to bring the ratio of the chip to the substrate closer, but also omit the conventional design of solder wire to reduce the impedance and improve the electrical properties to avoid distortion of signals during transmission process. Therefore, it has become the main stream packaging technology for the next generation of chips.

However, during the operation of a highly integrated semiconductor chip, a large amount of heat will be generated, and the packaging colloid covering the semiconductor chip is made of a poor heat transfer material with a thermal conductivity of only 0.8 W/mk. If the heat generated by the semiconductor chip cannot be effectively dissipated, it will cause damage to the semiconductor chip and product reliability issues. Hence, in order to improve the heat dissipation efficiency of the semiconductor package, the idea of adding heat sinks to the packages came into being.

As shown in FIG. 1, in the manufacturing method of a conventional flip-chip semiconductor package 1 integrated with a heat sink, a semiconductor chip 11 is disposed on a packaging substrate 10 via an active surface 11a thereof in a flip-chip bonding manner (i.e., via conductive bumps 110 and an underfill 111). Then, a heat sink 13 is directly added onto an inactive surface 11b of the semiconductor chip 11 via a thermal interface material (TIM) layer 12 without adhering the heat sink 13 to the packaging substrate 10. As such, the conductive bumps 110 that electrically connect the semiconductor chip 11 and the packaging substrate 10 will not bear the thermal stress caused by the CTE (coefficient of thermal expansion) difference between the heat sink 13 and the packaging substrate 10, thereby avoiding the problem of cracking.

However, this type of semiconductor package cannot be used to provide an effective solution to the substrate warping problem and will be even very sensitive to the substrate warping problem when having a large-sized chip. In a case of a large-sized chip, as long as the substrate has warping problem, the solder bumps on the edge of the chip done in a flip-chip manner will not be easily adhered to the substrate, thereby resulting in electrical connection failures.

Therefore, there is an urgent need in the art to provide a flip-chip semiconductor package that will not cause warping problem and can effectively provide ball placement flatness.

### SUMMARY

In view of the aforementioned shortcomings of the prior art, the present disclosure provides an electronic package, which comprises: a substrate; an electronic component disposed on and electrically connected to the substrate; an encapsulation layer formed on the substrate and covering the electronic component; and a frame body embedded in the encapsulation layer and protruding from the substrate.

The present disclosure further provides a method of manufacturing an electronic package, the method comprises: providing a substrate; disposing an electronic component and a frame body on the substrate, wherein the frame body is configured to protrude from the substrate; and forming an encapsulation layer on the substrate, wherein the encapsulation layer covers the electronic component and the frame body.

In the aforementioned electronic package and method, the present disclosure further comprises: providing a carrying structure; disposing a plurality of the substrates on the carrying structure; performing a singulation process on each of the substrates after forming the encapsulation layer; and removing the carrying structure.

In the aforementioned electronic package and method, the carrying structure is disposed with a supporting member thereon, and the supporting member has a plurality of openings, wherein the plurality of substrates are disposed in the plurality of openings respectively.

In the aforementioned electronic package and method, the encapsulation layer covers side surfaces of the substrate.

In the aforementioned electronic package and method, the frame body is annular and surrounds an outer periphery of the electronic component.

In the aforementioned electronic package and method, the frame body is distributed outside the electronic component in a discontinuous manner.

In the aforementioned electronic package and method, the frame body comprises a main body part and a bending part, wherein the main body part extends from an inside of the substrate to an outside of the substrate, and the bending part is connected to one end of the main body part protruding from the substrate and is perpendicular to the main body part.

In the aforementioned electronic package and method, the bending part of the frame body is opposite to a side surface of the substrate.

In the aforementioned electronic package and method, the frame body is partially exposed from the encapsulation layer.

In the aforementioned electronic package and method, the electronic component is partially exposed from the encapsulation layer.

In the aforementioned electronic package and method, the frame body is free from being in contact with the substrate.

In the aforementioned electronic package and method, the present disclosure further comprises forming a shielding layer on the encapsulation layer.

In the aforementioned electronic package and method, the frame body is made of metal material or semiconductor material.

In the aforementioned electronic package and method, a portion of the frame body protruding from a side surface of the substrate is suspended.

It can be seen from the above that in the electronic package and the manufacturing method thereof of the present disclosure, the thermal stress is dispersed by the frame body, thereby preventing the encapsulation layer from warping during thermal cycles. In addition, the frame body is configured to protrude from the substrate, such that other electronic components can be arranged around the electronic component without increasing the size of the substrate, thereby reducing the manufacturing cost.

### BRIEF DESCRIPTION OF THE DRAWINGS

FIG. 1 is a schematic cross-sectional view showing a conventional heat dissipation type semiconductor package.

FIG. 2A to FIG. 2D are schematic cross-sectional views illustrating a manufacturing method of an electronic package of the present disclosure.

FIG. 3A is a schematic top cross-sectional view of FIG. 2D.

FIG. 3B and FIG. 3C are schematic views showing other embodiments of FIG. 3A.

FIG. 4 is a schematic cross-sectional view of an electronic package according to another embodiment of the present disclosure.

FIG. 5A-1, FIG. 5B and FIG. 5C are schematic cross-sectional views of electronic packages according to other embodiments of the present disclosure.

FIG. 5A-2 is a schematic top cross-sectional view of FIG. 5A-1.

FIG. 6A and FIG. 6B are schematic cross-sectional views of electronic packages according to other embodiments of the present disclosure.

FIG. 7 is a schematic cross-sectional view of an electronic package according to yet another embodiment of the present disclosure.

FIG. 8 is a schematic cross-sectional view of an electronic package according to a further embodiment of the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “under,” “a,” “one,” “first,” “second,” and the like are merely used for clear explanation rather than limiting the practicable scope of the present disclosure, and thus, alterations or adjustments of the relative relationships thereof without essentially altering the technical contents should still be considered in the practicable scope of the present disclosure.

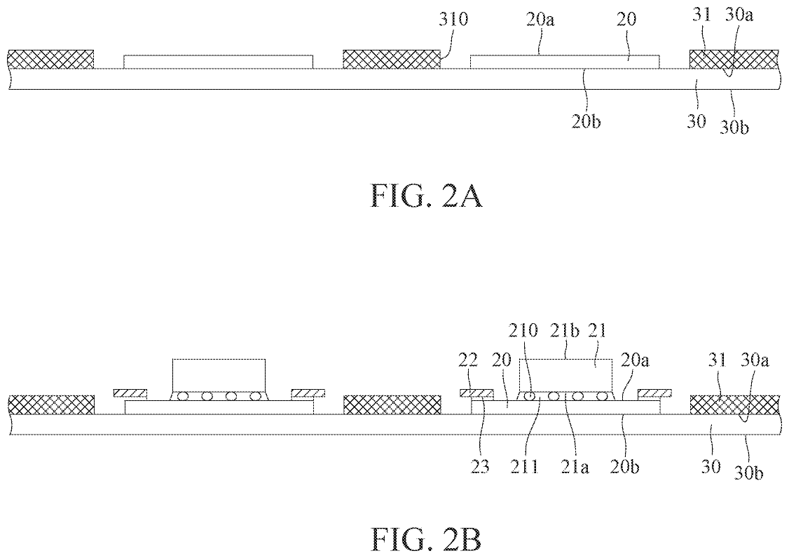

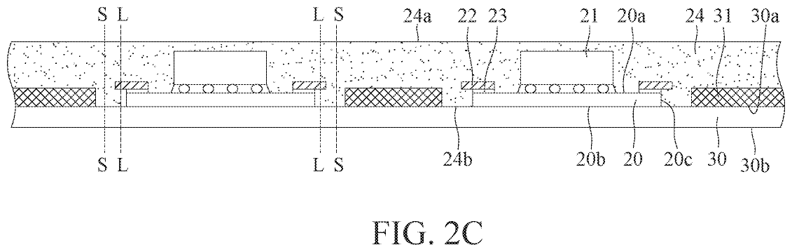

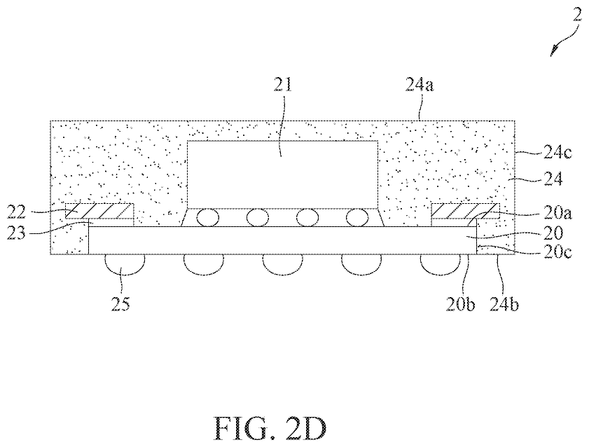

FIG. 2A to FIG. 2D are schematic cross-sectional views illustrating a manufacturing method of an electronic package 2 of the present disclosure.

As shown in FIG. 2A, a carrying structure 30 having a first side 30a and a second side 30b opposing the first side 30a is provided, and a supporting member 31 with a plurality of openings 310 is disposed on the first side 30a of the carrying structure 30, such that a substrate 20 is disposed in the opening 310 of the supporting member 31. In an embodiment, two substrates 20 are disposed in adjacent openings 310 respectively, but the present disclosure is not limited to as such.

The carrying structure 30 can be a temporary carrying board, which can for example comprise: a carrying board comprised of organic polymer board or copper foil substrate, but the present disclosure is not limited to as such.

The substrate 20 can be a packaging substrate with a core layer and a circuit portion, or a coreless circuit structure. In an embodiment, the substrate 20 comprises at least a dielectric layer and a circuit layer bonded with the dielectric layer, such as of a fan-out type redistribution layer (RDL) specification. The substrate 20 has a first side 20a and a second side 20b opposing the first side 20a, wherein the second side 20b of the substrate 20 is joined with the first side 30a of the carrying structure 30.

It can be understood that the substrate 20 can be other carrying units for carrying chips, such as a lead frame, a wafer, a silicon interposer, or other plates with metal routings, and the present disclosure is not limited to as such.

As shown in FIG. 2B, at least one electronic component 21 is disposed on the first side 20a of the substrate 20 via a plurality of conductive bumps 210, and an encapsulation layer such as an underfill 211 is formed between the first side 20a of the substrate 20 and the electronic component 21 to cover the plurality of conductive bumps 210.

The electronic component 21 is an active element, a passive element, or a combination of the active element and the passive element, wherein the active element is for example a semiconductor chip, and the passive element is a resistor, a capacitor, or an inductor. In an embodiment, the electronic component 21 is a semiconductor chip and has an active surface 21a and an inactive surface 21b opposing the active surface 21a, and a plurality of electrode pads (not shown) are formed on the active surface 21a, such that the plurality of electrode pads are bonded with and electrically connected to the circuit layer of the substrate 20 via the plurality of conductive bumps 210 made of such as solder material in a flip-chip manner.

In other embodiments, the electronic component 21 can be electrically connected to the circuit layer of the substrate 20 via a plurality of bonding wires in a wire bonding manner; alternatively, the electronic component 21 can be directly in contact with the circuit layer of the substrate 20. It can be understood that there are various ways for the electronic component 21 to be electrically connected to the substrate 20, and the substrate 20 can be disposed with the required type and quantity of the electronic component 21 thereon, and the present disclosure is not limited to as such.

Moreover, a frame body 22 is disposed on the first side 20a of the substrate 20 and protrudes from the side of the substrate 20.

The frame body 22 can be a metal frame made of such as copper, or a semiconductor frame made of such as silicon or glass, and the frame body 22 can be bonded to the substrate 20 via an adhesive layer 23 such as glue. In an embodiment, the frame body 22 is flat-shaped, and the frame body 22 is disposed parallel to the first side 20a of the substrate 20 and extends outward and protrudes from the substrate 20.

As shown in FIG. 2C, an encapsulation layer 24 is formed on the first side 30a of the carrying structure 30, such that the encapsulation layer 24 covers the supporting member 31, the substrate 20, the electronic component 21 and the frame body 22.

The encapsulation layer 24 has a first surface 24a and a second surface 24b opposing the first surface 24a. In an embodiment, the first surface 24a of the encapsulation layer 24 is higher than the inactive surface 21b of the electronic component 21 so that the encapsulation layer 24 completely covers the electronic component 21, and the second surface 24b of the encapsulation layer 24 is flush with the first side 30a of the carrying structure 30 and the second side 20b of the substrate 20.

In an embodiment, the encapsulation layer 24 is made of an insulating material such as polyimide (PI), dry film, molding colloid or molding compound of epoxy (epoxy resin). For instance, the encapsulation layer 24 can be formed on the first side 30a of the carrying structure 30 by liquid compound, injection, lamination, or compression molding.

As shown in FIG. 2D, a singulation process is performed on each of the substrates 20. In an embodiment, a cutting path S (as shown in FIG. 2C) is cut, so that the encapsulation layer 24 is defined with side surfaces 24c adjacent to the first surface 24a and the second surface 24b.

In an embodiment, the cutting path S is set such that the side surface 24c of the encapsulation layer 24 is located outside a side surface 20c of the substrate 20. In other words, the encapsulation layer 24 covers the side surfaces 20c of the substrate 20. Furthermore, in an embodiment, the frame body 22 protrudes from the side surface 20c of the substrate 20 but is not exposed from the side surface 24c of the encapsulation layer 24.

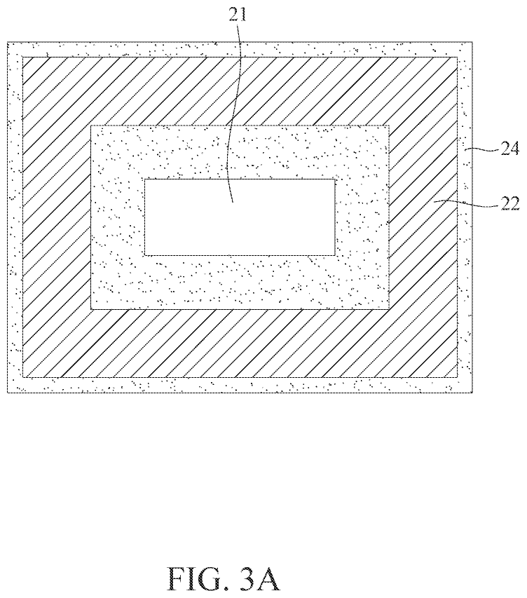

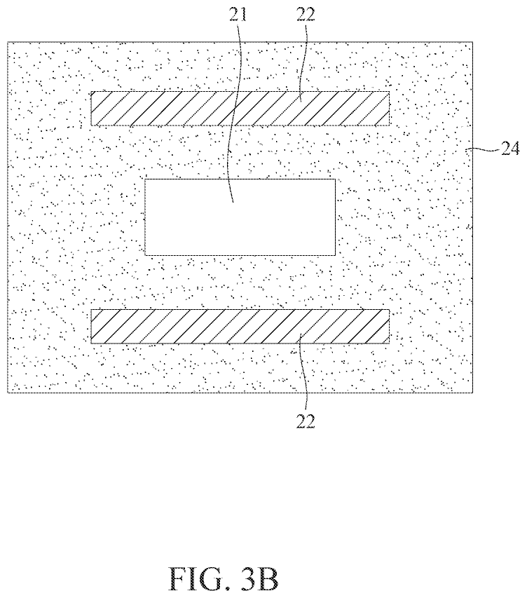

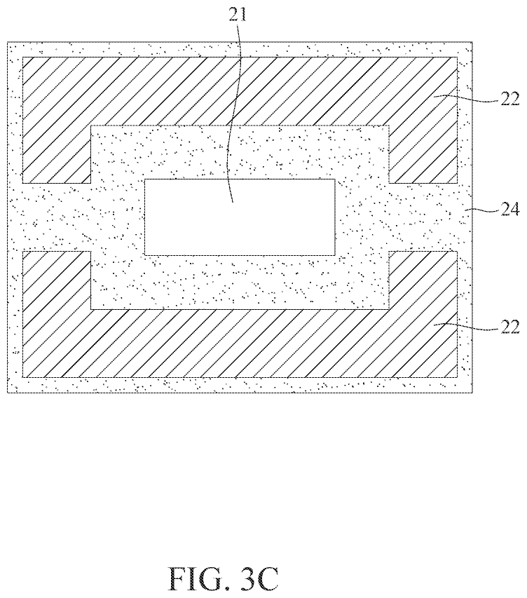

In addition, in an embodiment, as shown in FIG. 3A, the frame body 22 can be annular and continuously surrounds the outer periphery of the electronic component 21. Alternatively, in other embodiments, the frame body 22 can be distributed outside the electronic component 21 in a discontinuous manner (for instance, as shown in FIG. 3B, the frame body 22 can be symmetrically formed on opposite sides of the electronic component 21 and not connected with each other; or, as shown in FIG. 3C, the frame body 22 can surround the outer periphery of the electronic component 21 but be interrupted at the middle). Furthermore, the encapsulation layer 24 can be formed between the electronic component 21 and the frame body 22, and at the outer periphery of the frame body 22.

Moreover, after the carrying structure 30 is removed, a plurality of conductive components 25 such as metal pillars of copper posts, metal bumps covering with insulting blocks, solder balls, solder balls with copper core balls, or other conductive structures can be disposed on the second side 20b of the substrate 20, so as to obtain the electronic package 2 of the present disclosure.

Based on the above, in the manufacturing method of the present disclosure, the frame body 22 is designed to disperse the thermal stress, thereby preventing warping during thermal cycles. Additionally, since the frame body 22 protrudes from the substrate 20, other electronic components can be arranged around the electronic component 21 without increasing the size of the substrate 20, thereby reducing the manufacturing cost.

In the following, various implementation aspects of the aforementioned electronic package 2 of the present disclosure will be described in detail. The same or corresponding components between electronic packages 2a, 2b, 2c, 2d, 2e, 2f, 2g, 2h of different embodiments and the aforementioned electronic package 2 are labeled with the same or corresponding component symbols, and the same portions are omitted.

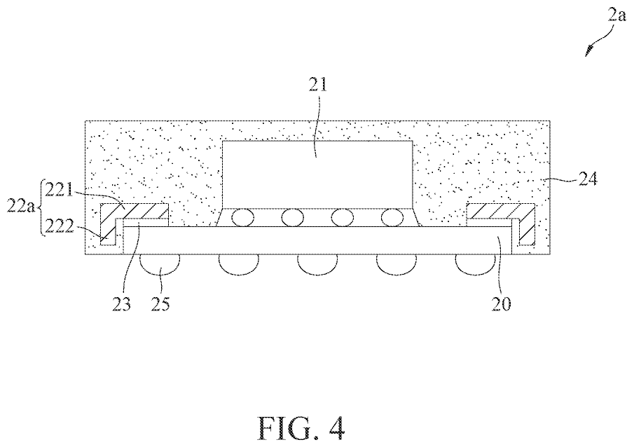

Firstly, FIG. 4 is a schematic cross-sectional view of the electronic package 2a of the present disclosure. As shown in FIG. 4, in the electronic package 2a, the longitudinal section of a frame body 22a can be formed as an L-shape, and the frame body 22a includes a main body part 221 and a bending part 222. The main body part 221 is disposed on the substrate 20 via the adhesive layer 23 and extends outside of the substrate 20, and the bending part 222 is connected to one end of the main body part 221 that protrudes from the substrate 20 and the bending part 222 is perpendicular to the main body part 221, such that the bending part 222 is parallel to the side surface 20c of the substrate 20 and opposite to the side surface 20c of the substrate 20. By forming the frame body 22a into an L-shape, thermal stress can be dispersed well, thereby preventing warping during thermal cycles.

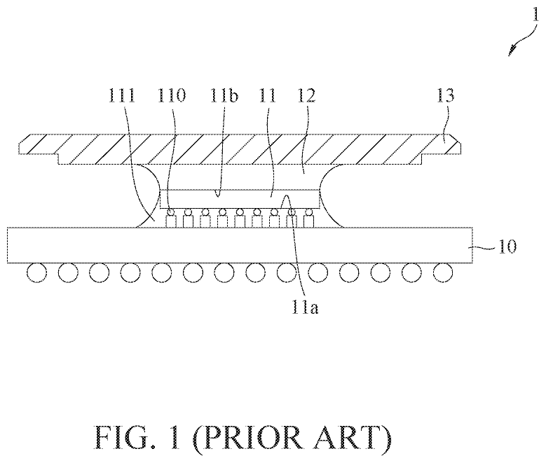

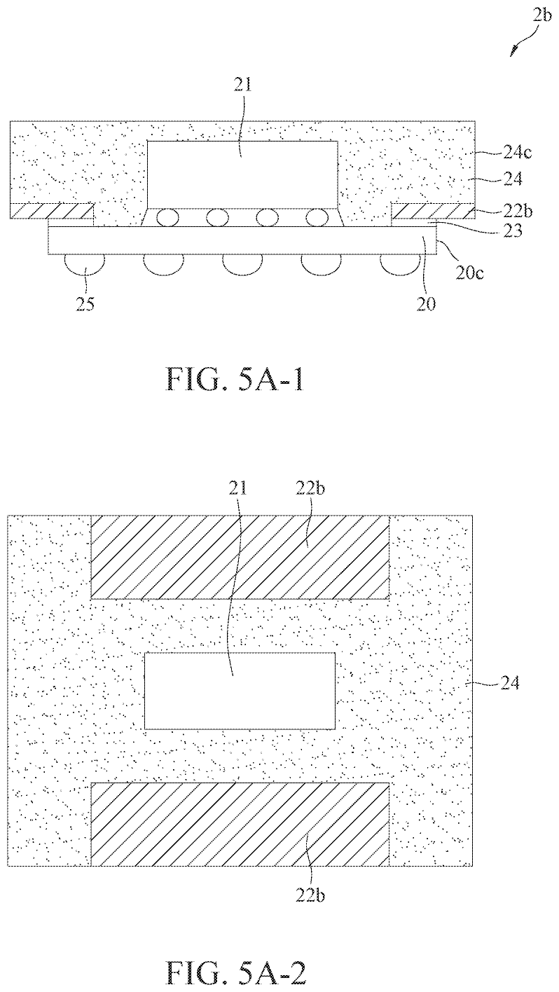

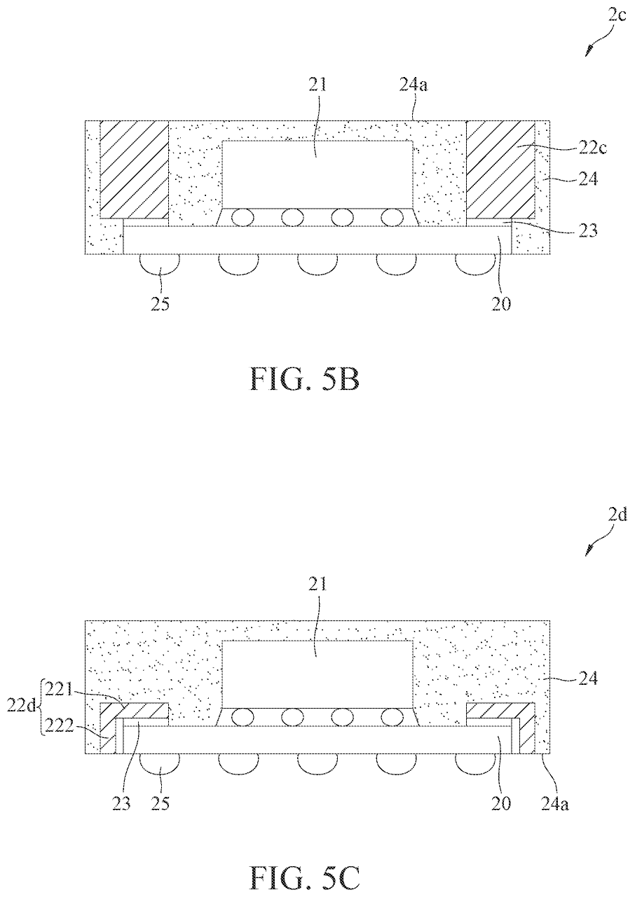

Moreover, FIG. 5A-1, FIG. 5B and FIG. 5C are schematic cross-sectional views of the electronic packages 2b, 2c, 2d of the present disclosure. As shown in FIG. 5A-1, FIG. 5B and FIG. 5C, in the electronic packages 2b, 2c, 2d, frame bodies 22b, 22c, 22d can be partially exposed from the encapsulation layer 24. Specifically, the length of the frame body 22b in the lateral direction can be increased, so that the frame body 22b is exposed from the side surface 24c of the encapsulation layer 24, and the portion of the frame body 22b protruding from the side surface 20c of the substrate 20 can even be suspended without disposing an encapsulation layer 24 thereunder (as shown in FIG. 5A-1); or, the height of the frame body 22c in the up and down direction can be increased, so that the frame body 22c is exposed from the first surface 24a of the encapsulation layer 24 (as shown in FIG. 5B); alternatively, when the frame body 22d is L-shaped, the length of the bending part 222 of the frame body 22d can be increased, so that the frame body 22d extends downward to and is exposed from the second surface 24b of the encapsulation layer 24 (as shown in FIG. 5C). By exposing part surfaces of the frame bodies 22b, 22c, 22d from the encapsulation layer 24, the thermal cycles can be promoted well.

Furthermore, in addition to changing the shape and size of the frame bodies 22b, 22c, 22d, the cutting path of the singulation process also can be changed to have the frame bodies 22b, 22c, 22d exposed from the encapsulation layer 24. For instance, if a cutting path Lis cut to have the cutting path pass through the frame body 22b, the frame body 22b can be exposed when the shape and size of the frame body 22b are unchanged. It can be understood that the cutting path of the singulation process can be set according to requirements and is not particularly limited.

Moreover, FIG. 5A-2 is a schematic top cross-sectional view of FIG. 5A-1. As shown in FIG. 5A-2, the frame body 22b can be symmetrically formed on two opposite sides of the electronic component 21, and a portion of the surface of the frame body 22b is exposed from the side surface 24c of the encapsulation layer 24. However, the present disclosure is not limited to as such, the frame body 22b can also be formed in annular shape with a continuous or discontinuous manner, or the shape or size of the frame body 22b can be changed according to requirements.

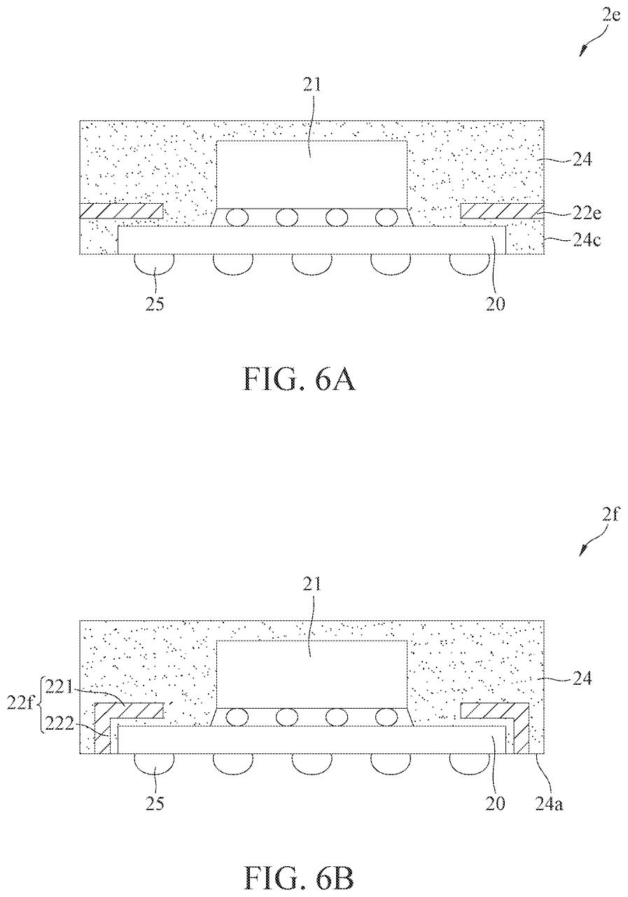

Furthermore, FIG. 6A and FIG. 6B are schematic cross-sectional views of the electronic packages 2e, 2f of the present disclosure. As shown in FIG. 6A and FIG. 6B, in the electronic packages 2e, 2f, frame bodies 22e, 22f can be free from being in contact with the substrate 20 and not be joined to the substrate 20, so that the encapsulation layer 24 is formed between the substrate 20 and the frame bodies 22e, 22f.

In order to manufacture this structure, the step shown in FIG. 2B can be adjusted so that the frame bodies 22e, 22f are not directly disposed on the substrate 20. For instance, the frame body 22e in flat-shape can be set on the supporting member 31 and extends above the substrate 20 without contacting the substrate 20, such that the electronic package 2e (as shown in FIG. 6A) can be obtained after the encapsulation layer 24 is formed and the singulation process is conducted; alternatively, the frame body 22f in L-shape can be erected between the supporting member 31 and the substrate 20 by using the bending part 222, so that the main body part 221 of the frame body 22f extends above the substrate 20 without contacting the substrate 20, such that the electronic package 2f (as shown in FIG. 6B) can be obtained after the encapsulation layer 24 is formed and the singulation process is conducted. It can be understood that the aforementioned manufacturing methods are only exemplary embodiments for illustration, and different methods can also be used to manufacture the electronic packages 2e, 2f.

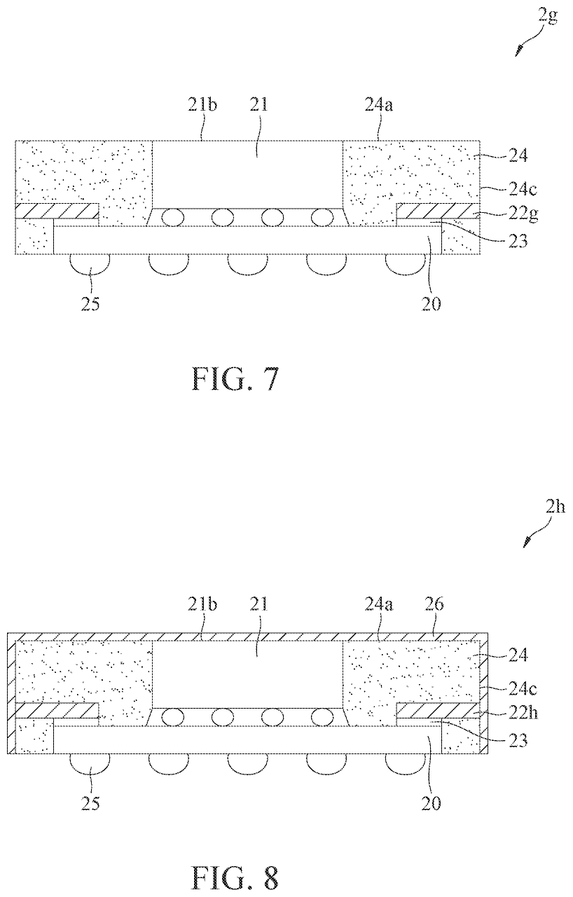

In addition, FIG. 7 is a schematic cross-sectional view of the electronic package 2g of the present disclosure. As shown in FIG. 7, in the electronic package 2g, the inactive surface 21b of the electronic component 21 is exposed from the first surface 24a of the encapsulation layer 24. To this end, a portion of the material of the encapsulation layer 24 (even a portion of the material of the inactive surface 21b of the electronic component 21) can be removed by leveling process such as grinding, so that the first surface 24a of the encapsulation layer 24 is flush with the inactive surface 21b of the electronic component 21, such that the inactive surface 21b of the electronic component 21 is exposed from the first surface 24a of the encapsulation layer 24. Hence, the heat dissipation efficiency of the electronic component 21 itself can be improved, thereby improving thermal cycles.

Moreover, a frame body 22g of the electronic package 2g shown in FIG. 7 is exposed from the side surface 24c of the encapsulation layer 24, but the present disclosure is not limited to as such, the frame body 22g can also be exposed from the first surface 24a or the second surface 24b of the encapsulation layer 24, or the frame body 22g can also be free from being exposed from the encapsulation layer 24.

Additionally, FIG. 8 is a schematic cross-sectional view of the electronic package 2h of the present disclosure. As shown in FIG. 8, in the electronic package 2h, based on the electronic package 2g of FIG. 7, after conducting a singulation process, a shielding layer 26 is formed on the side surfaces 24c and the first surface 24a of the encapsulation layer 24, so that the shielding layer 26 is in contact with a frame body 22h at the side surface 24c of the encapsulation layer 24, and the shielding layer 26 is in contact with the electronic component 21 at the first surface 24a of the encapsulation layer 24. Moreover, when the shielding layer 26 is formed based on other embodiments, the shielding layer 26 can also be in contact with the frame body 22h at the first surface 24a or the second surface 24b of the encapsulation layer 24, or the shielding layer 26 can be free from being in contact with the frame body 22h. It should be understood that the shielding layer 26 can be in contact with or free from being in contact with the electronic component 21 according to requirements, and is not particularly limited.

Therefore, in the manufacturing method of the present disclosure, the shielding layer 26 is designed to prevent the electronic component 21 from electromagnetic interference (EMI).

The present disclosure also provides an electronic package 2, 2a, 2b, 2c, 2d, 2e, 2f, 2g, 2h, which comprises: a substrate 20, an electronic component 21, an encapsulation layer 24, and a frame body 22, 22a, 22b, 22c, 22d, 22e, 22f, 22g, 22h.

The electronic component 21 is disposed on the substrate 20 and electrically connected to the substrate 20.

The encapsulation layer 24 is formed on the substrate 20 and covers the electronic component 21, wherein the encapsulation layer 24 has a first surface 24a, a second surface 24b opposing the first surface 24a, and side surfaces 24c adjacent to the first surface 24a and the second surface 24b, wherein the second surface 24b of the encapsulation layer 24 is flush with the second side 20b of the substrate 20.

The frame body 22, 22a, 22b, 22c, 22d, 22e, 22f, 22g, 22h is embedded in the encapsulation layer 24, and the frame body 22, 22a, 22b, 22c, 22d, 22e, 22f, 22g, 22h protrudes from the substrate 20.

In an embodiment, the encapsulation layer 24 covers side surfaces 20c of the substrate 20.

In an embodiment, the frame body 22 is annular and surrounds an outer periphery of the electronic component 21.

In an embodiment, the frame body 22 is distributed outside the electronic component 21 in a discontinuous manner.

In an embodiment, the frame body 22a, 22d, 22f comprises a main body part 221 and a bending part 222, wherein the main body part 221 extends from the inside of the substrate 20 to the outside of the substrate 20, and the bending part 222 is connected to one end of the main body part 221 protruding from the substrate 20 and is perpendicular to the main body part 221.

In an embodiment, the bending part 222 of the frame body 22a, 22d, 22f is opposite to the side surface 20c of the substrate 20.

In an embodiment, the frame body 22b, 22c, 22d, 22e, 22f, 22g is partially exposed from the encapsulation layer 24.

In an embodiment, the electronic component 21 is partially exposed from the encapsulation layer 24.

In an embodiment, the frame body 22e, 22f is free from being in contact with the substrate.

In an embodiment, the electronic package 2h further comprises a shielding layer 26 formed on the encapsulation layer 24.

In an embodiment, the frame body 22, 22a, 22b, 22c, 22d, 22e, 22f, 22g, 22h is made of metal material or semiconductor material.

To sum up, in the electronic package and the manufacturing method thereof of the present disclosure, the frame body is designed to disperse the thermal stress inside the electronic package, thereby preventing the encapsulation layer from warping during thermal cycles.

In addition, the frame body is configured to protrude from the substrate, and the frame body merely occupies a small portion of the space outside the substrate, so that other electronic components can be arranged around the electronic component without increasing the size of the substrate, thereby reducing the manufacturing cost.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a substrate;
an electronic component disposed on and electrically connected to the substrate;
an encapsulation layer formed on the substrate and covering the electronic component; and
a frame body embedded in the encapsulation layer and protruding from the substrate.

2. The electronic package of claim 1, wherein the encapsulation layer covers side surfaces of the substrate.

3. The electronic package of claim 1, wherein the frame body is annular and surrounds an outer periphery of the electronic component.

4. The electronic package of claim 1, wherein the frame body is distributed outside the electronic component in a discontinuous manner.

5. The electronic package of claim 1, wherein the frame body comprises a main body part and a bending part, wherein the main body part extends from an inside of the substrate to an outside of the substrate, and the bending part is connected to one end of the main body part protruding from the substrate and is perpendicular to the main body part.

6. The electronic package of claim 5, wherein the bending part of the frame body is opposite to a side surface of the substrate.

7. The electronic package of claim 1, wherein the frame body is partially exposed from the encapsulation layer.

8. The electronic package of claim 1, wherein the electronic component is partially exposed from the encapsulation layer.

9. The electronic package of claim 1, wherein the frame body is free from being in contact with the substrate.

10. The electronic package of claim 1, further comprising a shielding layer formed on the encapsulation layer.

11. The electronic package of claim 1, wherein the frame body is made of metal material or semiconductor material.

12. The electronic package of claim 1, wherein a portion of the frame body protruding from a side surface of the substrate is suspended.

13. A method of manufacturing an electronic package, the method comprising:
providing a substrate;
disposing an electronic component and a frame body on the substrate, wherein the frame body is configured to protrude from the substrate; and
forming an encapsulation layer on the substrate, wherein the encapsulation layer covers the electronic component and the frame body.

14. The method of claim 13, further comprising:
providing a carrying structure;
disposing a plurality of the substrates on the carrying structure;
performing a singulation process on each of the substrates after forming the encapsulation layer; and
removing the carrying structure.

15. The method of claim 14, wherein the carrying structure is disposed with a supporting member thereon, and the supporting member has a plurality of openings, wherein the plurality of substrates are disposed in the plurality of openings respectively.

16. The method of claim 13, wherein the encapsulation layer covers side surfaces of the substrate.

17. The method of claim 13, wherein the frame body is annular and surrounds an outer periphery of the electronic component.

18. The method of claim 13, wherein the frame body is distributed outside the electronic component in a discontinuous manner.

19. The method of claim 13, wherein the frame body comprises a main body part and a bending part, wherein the main body part extends from an inside of the substrate to an outside of the substrate, and the bending part is connected to one end of the main body part protruding from the substrate and is perpendicular to the main body part.

20. The method of claim 19, wherein the bending part of the frame body is opposite to a side surface of the substrate.

21. The method of claim 13, wherein the frame body is partially exposed from the encapsulation layer.

22. The method of claim 13, wherein the electronic component is partially exposed from the encapsulation layer.

23. The method of claim 13, wherein the frame body is free from being in contact with the substrate.

24. The method of claim 13, further comprising forming a shielding layer on the encapsulation layer.

25. The method of claim 13, wherein the frame body is made of metal material or semiconductor material.

26. The method of claim 13, wherein a portion of the frame body protruding from a side surface of the substrate is suspended.
